(19) United States
(12) Patent Application Publication
(10) Pub. No.: US 2017/0003336 A1
(43) Pub. Date: Jan. 5, 2017

(54) DIAMOND DELAYERING FOR ELECTRICAL PROBING

(71) Applicant: DCG Systems, Inc., Fremont, CA (US)

(72) Inventors: Stephen Ippolito, Saint Petersburg, FL (US); Sean Zumwalt, Oxnard, CA (US); Andrew Norman Erickson, Santa Barbara, CA (US)

(73) Assignee: DCG Systems, Inc., Fremont, CA (US)

(21) Appl. No.: 15/182,571

(22) Filed: Jun. 14, 2016

Related U.S. Application Data
(60) Provisional application No. 62/180,034, filed on Jun. 15, 2015.

(51) Int. Cl. G01R 31/26; G01Q 80/00

(52) U.S. Cl. CPC G01R 31/2601; G01Q 80/00

(57) ABSTRACT

Milling using a scanning probe microscope with a diamond tip removes a layer of material and produces a surface that is sufficiently smooth that it can be probed using a nanoprober to provide site-specific sample preparation and delayering. Diamond milling provides in situ, localized, precision delayering inside of a nanoprobing tool, thereby decreasing the turnaround time for integrated circuit analysis. Furthermore, unlike focused ion beam delayering, the diamond tip should not alter the electrical characteristics of the integrated circuit.

### TECHNICAL FIELD OF THE INVENTION

The present invention relates to scanning probe microscopes and processing methods using scanning probe microscopes.

### BACKGROUND OF THE INVENTION

The scanning probe microscope has been a cornerstone for nano-probing integrated circuits, due its precise force control, nanometer-scale resolution, and nondestructive nature. New capabilities, such as scanning conductance, scanning capacitance, pulsed current-voltage measurement, and capacitance-voltage spectroscopy, have been widely adopted by the integrated circuit analysis community. The most common type of scanning probe microscope is the atomic force microscope (AFM) and the term AFM is often used to refer to any type of SPM. As used herein, atomic force microscope or AFM can refer to any type of scanning probe microscope.

Modern integrated circuits are fabricated using multiple layers of semiconductors, insulators, and conductors. To investigate a subsurface layer by electrical probing, it is often necessary to remove overlying layers to make electrical contact with the subsurface layers. Preparation of integrated circuits for nano-probing, or, for that matter, other probing techniques, typically involves the global delayering of a die with mechanical polishing to the desired layer.

Dimpling and computer numerical control milling tools have also been employed to more locally delayer (typically at the millimeter scale). However, these methods become more time-consuming, risky, and challenging as layer thicknesses decrease. One such challenge is the requirement to provide a surface for nanoprobing that is clean, conductive, and at the desired level. Another challenge is the requirement to provide a large area for nanoprobing at the appropriate level, because different regions often polish at different rates. In early technology nodes, levels tended to be etch-selective and self-planarized on metal or dielectric layers. Thus, the integrated circuit could be delayered uniformly to any desired level. However, for advanced technologies, it is increasingly difficult to provide all of these properties in one process.

As a surface electrical failure analysis technique, nanoprobing can be performed on either a single interconnect layer or a sequence of multiple interconnect layers, with delayering steps in between. If front-end devices are suspected and back-end metal defects can be ruled out, a single sample-preparation step and subsequent nanoprobing can usually achieve high levels of success. However, it is often necessary to check the interconnect layer by layer with nanoprobing to verify if a defect (open or short) is still present. In the past, this type of job required removal of the integrated circuit from the nanoprobing tool, removal of a metal layer, and placement of the modified integrated circuit back in the tool for another round of nanoprobing. When an analysis must sequentially nanoprobe four to ten layers of metal, the turnaround time and success rate of the analysis becomes problematic.

For site-specific delayering, failure analysts often use focused ion beam (FIB) milling, as an alternative to mechanical delayering techniques. In the case of layer-by-layer analysis, the FIB is used to either open a window or cut traces to isolate defects. While this may be effective in the case of gross defects, changes in electrical characteristics are often associated with the FIB milling process itself, instead of the removal of the defective layer. Focused ion beam milling with a gallium beam significantly alters subsequent electrical measurements by charging associated layers with the high-energy gallium ion impacts, as well as by introducing significant leakage paths from gallium deposition and implantation. Thus, during critical device probing, it is difficult to rule out whether an electrically measured defect is intrinsic or caused by the FIB milling process itself. Focused ion beam milling with a xenon beam was recently introduced. It is a promising alternative to gallium, but its charging effects have yet to be characterized.

U.S. Pat. No. 6,353,219 to Kley for “Object Inspection and/or Modification System and Method” describes using a scanning probe microscope to remove material, which Kley indicated is particularly useful for performing a precise cut to remove extra material from a semiconductor wafer or mask. Different tips with different cutting angles and crystal orientations are available to be lowered onto the sample with sufficient force to cut the sample as the tip is dragged. The tip has a core that comprises a conductive or semiconductive material, such as silicon or silicon nitride. The core is coated with an obdurate coating, such as diamond, silicon carbide, carbon nitride, diamond like carbon, or some other obdurate material. The coating can be grown on the core to form a single crystal plate.

U.S. Pat. No. 7,375,324 to Linder for a “Stylus System for Modifying Small Structures” describes moving a stylus-nano-profilometer probe in rapid lateral strokes across a sample surface in a definable pattern at known high applied pressure to effectuate defect repair. The tip of the probe can also be dithered rapidly in a pattern or used as to create a jackhammer effect to more effectively remove material from the sample surface. The probe tip can be composed of diamond.

AFMs have been used to remove material, such as excess material on a photolithography mask. For example, U.S. Pat. No. 7,946,020 to Kley for “Manufacturing of Micro-Objects such as Miniature Diamond Tool Tips” describes a method for affixing a diamond tip to an AFM.

US. Pat. Pub. 2015/0214124 of Buxbaum describes using a probe tip having a cutting edge to mechanically peel off a layer of material of an integrated circuit.

### SUMMARY OF THE INVENTION

An object of the invention is to provide site-specific delayering of a sample to provide electrical access to contact a probe to a subsurface layer.

Milling using a scanning probe microscope with a diamond tip removes a layer of material and produces a surface that is sufficiently smooth that it can be probed using a nanoprober to provide site-specific sample preparation and delayering. Diamond milling provides in situ, localized, precision delayering inside of a nanoprobing tool, thereby decreasing the turnaround time for integrated circuit analysis. Furthermore, unlike focused ion beam delayering, the diamond tip should not alter the electrical characteristics of the integrated circuit.

The foregoing has outlined rather broadly the features and technical advantages of the present invention in order that the detailed description of the invention that follows may be better understood. Additional features and advantages of the invention will be described hereinafter. It should be appreciated by those skilled in the art that the conception and specific embodiments disclosed may be readily utilized as a basis for modifying or designing other structures for carrying out the same purposes of the present invention. It should also be realized by those skilled in the art that such equivalent constructions do not depart from the scope of the invention as set forth in the appended claims.

### BRIEF DESCRIPTION OF THE DRAWINGS

For a more thorough understanding of the present invention, and advantages thereof, reference is now made to the following descriptions taken in conjunction with the accompanying drawings, in which:

FIG. 1A shows a scanning probe microscope milling in a first direction;

FIG. 1B shows a scanning probe microscope milling in a second direction;

FIG. 2A shows an AFM image of a 3 μm by 3 μm area, which includes the milling region; FIG. 2B shows a line cut across the milled region of FIG. 2A;

FIG. 3A shows an AFM topography image of a region milled using a diamond probe tip; FIG. 3B shows a conductive image at −0.5 V of the region of FIG. 3A; FIG. 3C shows a conductive image at 0.5 V of the region of FIG. 3A;

FIG. 4A shows an AFM topography image of another region milled using a diamond probe tip; FIG. 4B shows a conductive image of the region of FIG. 4A;

FIG. 5A shows an AFM topography image of yet another region milled using a diamond probe tip; FIG. 5B shows a conductive image of the region of FIG. 5A;

FIG. 6 shows a nanoprobing configuration for electrical measurements of different layers of an integrated circuit;

FIGS. 7A and 7B show electrical measurements from the probe configuration of FIG. 6, with FIG. 7A showing the gate voltage sweep of a transfer device and FIG. 7B showing the drain voltage sweep of another transfer device;

FIG. 8A shows a diamond tipped AFM probe; FIG. 8B shows an enlarged view of the end of the diamond probe tip;

FIG. 9 is a flow chart showing steps for delayering a circuit for electrical probing;

FIG. 10A shows a first scan strategy for a first step for delayering a circuit; FIG. 10B shows a first scan strategy for a second step for delayering the circuit;

FIG. 11A shows a second scan strategy for a first step for delayering a circuit; FIG. 11B shows a second scan strategy for a second step for delayering the circuit; and

FIG. 12 is a flowchart showing a method of evaluating a circuit.

### DETAILED DESCRIPTION OF PREFERRED EMBODIMENTS

Embodiments of the invention provide a method and apparatus for using a scanning probe microscope (SPM) to mill an area of an integrated circuit to delayer the area to expose a buried layer for electrical probing. The SPM preferably uses a single crystal diamond tip. Surprisingly, the SPM can provide a surface that is sufficiently smooth for nano-probing.

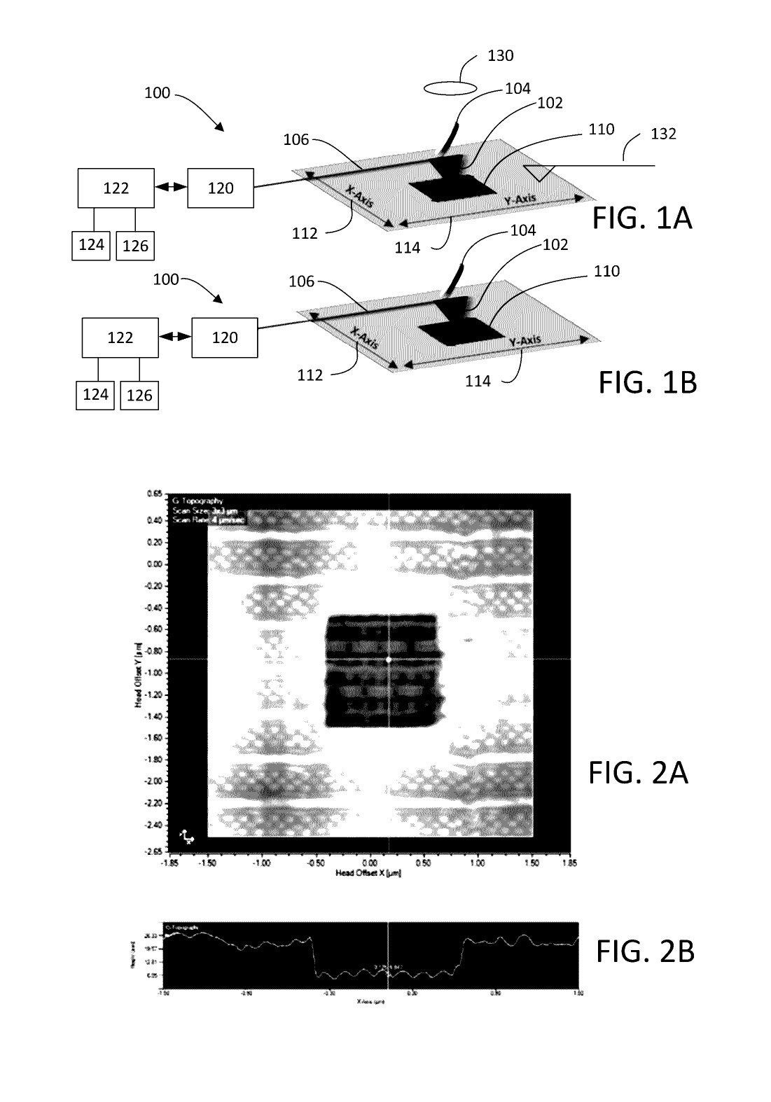

FIGS. 1A and 1B show schematically an AFM 100 having single-crystal, faceted diamond tip 102 and a retro-reflecting mirror 104 mounted on the end of an AFM cantilever 106. The preferred end radius of the diamond tip will depend on the hardness of the material to be milled and the precision required for the mill The end radius is typically between 5 nm and 40 nm, with an end radius of approximately 10 nm preferred. The AFM 100 is used to mill a region 110 to expose a buried layer for electrical probing. The arrows shown in region 110 indicate the primary scan direction of the probe tip 102. In FIG. 1A, the probe is shown moving back and forth along the x-axis 112 while it move incrementally along the y-axis 114, that is, the probe is scanned in a raster pattern. The preferred scan speed depends on hardness and milling behavior of the material being milled, and is typically between about 10 μm/sec and 100 μm/sec, with approximately 25 μm/sec is preferred in some applications. An optical microscope 130 allows a user to observe the operation of the AFM, to position the probe 102 and to observe the results of the milling. Alternatively, the process can be performed in a vacuum and the sample can be images using an electron microscope. A second probe 132 facilitates electrical probing of the area exposed by AFM 100. Probe 132 can be included in a multi-headed AFM, which provides a convenient package for milling and probing. A multi-headed AFM also allows verification of completed milling pattern (checking “pocket” or “cut” with other probe tips).

Movement in the y-direction can be continuous and simultaneous with the movement back and forth in the +/− x-direction, or the probe can be moved only in the +/− x-direction, and then stepped in the y-direction before the next scan in the x-direction. Cantilever 106 is moved by an actuator 120 having nanometer-scale precision. Actuator 120 is controlled by controller 122, which may receive instructions from a user by way of a user interface 124 or from a program stored in a computer memory 126. FIG. 1B shows the AFM of FIG. 1A, with the scanning pattern rotated ninety degrees, that is, the probe is shown moving back and forth along the y-axis 114 while it move incrementally along the x-axis 112. First scanning region 110 in the direction shown in FIG. 1A and then scanning region 110 in the direction shown in FIG. 1B produces a smoother surface than scanning in a single direction.

Several experiments were conducted to determine the optimal process for delayering a 1 μm by 1 μm area in a static random access memory region of a 22 nm integrated circuit with the diamond probe from the second metal level to the first metal level.

Milling was conducted with a triangle wave (constant velocity) scan in the forward and reverse direction for each line in the milled area 110, as illustrated schematically in FIG. 1A. For milling, the STM was operated in constant height mode, that is, the actuator 120 applied pressure to the probe to maintain the scan at a constant height, relative to and typically below, the sample surface. A second scan, orthogonal to the first scan, was then conducted on the same area with the fast and slow axes switched, as illustrated schematically in FIG. 1B. Finally, the diamond probe was scanned over the area in constant-force contact mode to sweep the surface of the removed material. Although the integrated circuit is composed of relatively hard materials, these materials are easily cut by the diamond, which is more than an order of magnitude harder than most materials used in semiconductors.

Contact imaging of a 3 μm by 3 μm area, which includes the 1 μm×1 μm milling region, is shown in FIG. 2A. The first metal level is clearly visible in the milled region, while the second metal level in the surrounding region remains undisturbed. A line cut across the milled region of the image is shown in FIG. 2A, which indicates 20 nm of height difference between the metal levels, as well as the generated topography on the first metal level, due to the difference in material-removal rates for the metal and dielectric. In a multi-headed AFM, the sequential use of a diamond milling probe and then a finer tungsten electrical probe will provide in situ milling capability for sample preparation and delayering, and then the electrical probing. The diamond milling process should not alter the electrical characteristics of the integrated circuit. In various embodiments the diamond probe has also been used to mill trenches in silicon as a method of marking cross-sectional scanning capacitance samples. It should be noted that the shape of the diamond tip determines the maximum vertical aspect ratio of diamond-milled trenches.

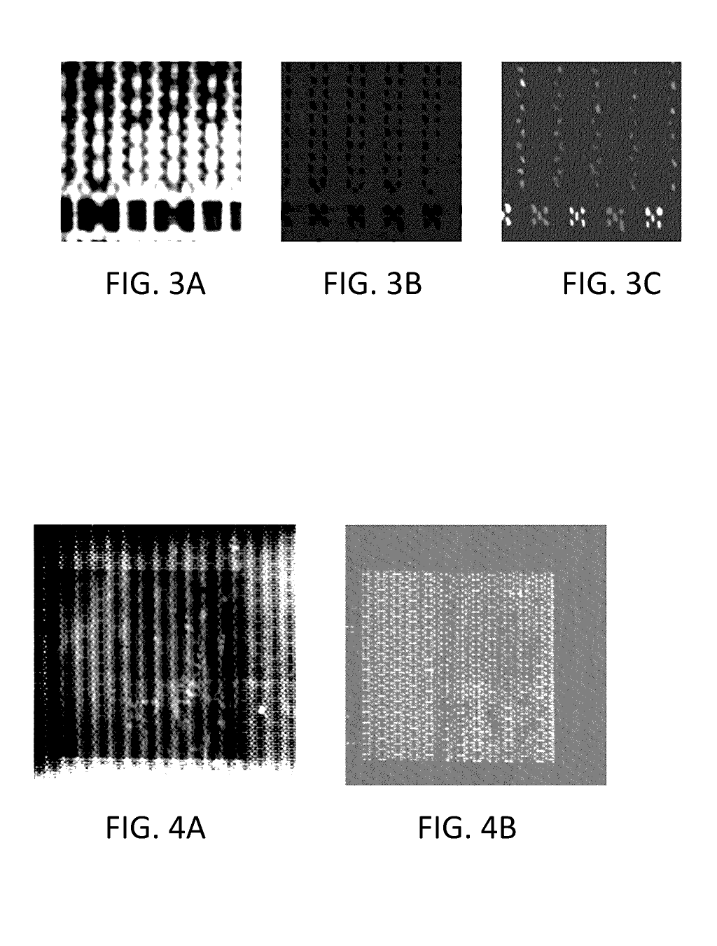

FIGS. 3A-3C show images obtained using a tungsten probe of the same 2 μm by 2 μm area inside the previously milled area. An AFM topography image in contact mode is shown in FIG. 3A, and corresponding conductance images taken with −0.5V and 0.5V probe bias, are shown in FIGS. 3B and 3B, respectively. These conductance images demonstrate the excellent conductance of the milled surface.

As a second example, a non-conductive cap layer was milled off to demonstrate that nanometers of material can be removed in a controlled fashion for surface preparation prior to nanoprobing. An AFM topography image is shown in FIG. 4A, and a corresponding conductance image is shown in FIG. 4B demonstrate the improvement in conductivity after milling with a diamond probe.

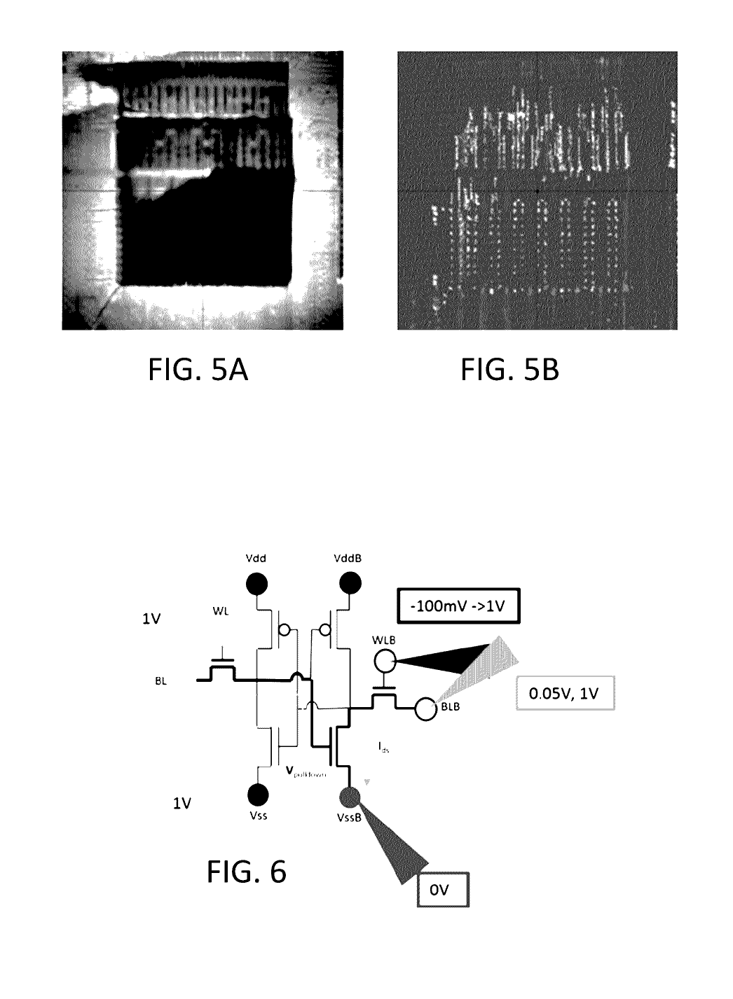

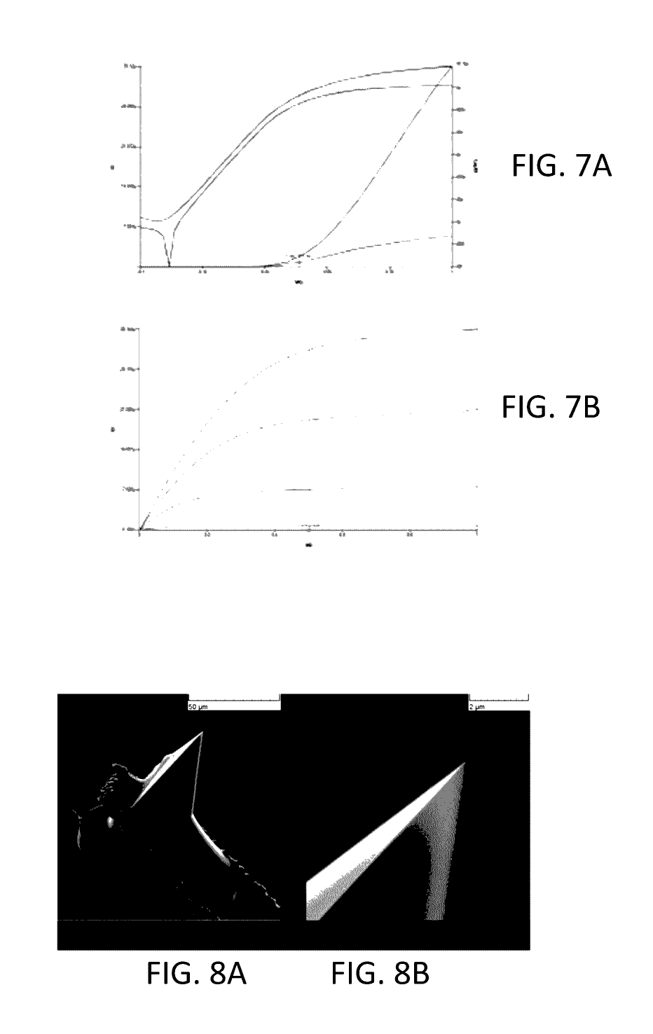

In a third demonstration, multiple levels (steps) were milled in an SRAM region of an integrated circuit fabricated by 14 nm process to demonstrate nanoprobing. Milling step depths of 20 nm, 40 nm, and 60 nm were made, using the diamond probe, starting from the top. An AFM topography image, acquired in contact mode with a tungsten probe, is shown in FIG. 5A, and the corresponding conductance image is shown in FIG. 5B. All of the circuitry from the upper level to the target, via layer in the deepest area is exposed and conductive. Thus, the diamond milling technique permits access to multiple layers within the same area. Measurements were conducted with multiple nanoprobes in the deepest area to contact a transistor in an SRAM cell while a well contact was nanoprobed in the upper level with the nanoprobing configuration shown in FIG. 6. Excellent contact resistance was observed of a transfer and pulldown device in a six transistor cell. FIG. 7A shows a gate voltage sweep of a transfer device (WLB wordline) with 0.05 V and 0.95 V applied to the bitline. FIG. 7A shows a drain voltage sweep of transfer device (BLB bitline). In the nanoprobing tool used to perform this work, milling, sweeping, and measuring are all carried out in an inert nitrogen-purged environment, so the milled area was clean, conductive, and at the correct layer for the nanoprobing measurements.

FIG. 8A shows a single-crystal, faceted diamond tip and a retro-reflecting mirror mounted on the end of an AFM cantilever. FIG. 8B shows an enlarged view of the diamond probe shown in FIG. 8A. In standard diamond attachment techniques, the diamond tip has a vertical orientation which would block observation of the contact point by the diamond tip and the work piece a top-mounted optical microscope. In a preferred embodiment, the diamond is mounted at an angle so that it extends from under the cantilever sufficiently forward that the contact point can be seen. This improved visibility of the tip also facilitates bringing the diamond tip into close proximity to the electrical measurement tips (within nanometers) and aids in the relocation of an ROI after milling. The crystal facets are preferably oriented relative to the cantilever such that a “flat” facet is facing “backwards” down the cantilever whereas a vertex would be pointing “forward” off the end of the cantilever.

The cantilever properties, particularly those related to spring constant, are adjusted to provide an appropriate compromise between two competing variables: the ability to apply force, and the ability to be extremely sensitive to force. That is, it is preferable to be able to not only mill with the tip, but also image with the tip gently enough to avoid damage or change the surface in an imaging mode. The tip is preferably able to image in both a contact-mode feedback system and a “tapping-mode” feedback system.

The milling properties vary with the milling direction, the variation being determined in part by the orientation of the cantilever. For most milling application, the preferred raster direction is substantially normal to the entrance angle of the cantilever—meaning the tip would normally scan side-to-side instead of forward and backwards. “Substantially normal” means at an angle within 30 degrees of the normal. This scan direction produces a more consistent milling. Milling in the forward-to-backwards direction, that is, parallel to the cantilever, for the cantilever, referred to as the “plow” direction, was found to remove material more aggressively (i.e., higher removal rates) but less controllably.

Milling in both directions in an alternating fashion was found to be helpful in maintaining regularity in the milling of the surface—however there was found to be a need to have different levels of deflection applied to the tip depending on mill direction to control for the undesirable “plowing.”

Scanning probe microscope milling does not produce vertical sidewalls due to the geometry of the diamond. It was found that that sidewall angle are approximately 45 degrees. This angle is considered when designing the strategy for milling a region. The sidewalls can interfere with cutting at the edges and were frequently very irregular.

To avoid problems caused by the sidewalls when milling deeper pockets applicant has found that a “terraced” approach is preferred to maintain control of the pocket geometry. In a terraced approach, multiple areas are scanned, each subsequently scanned area is a subset of the previously scanned area. That is, each subsequent scan is positioned within and is slightly smaller than the previous area. The walls of each successive are sufficiently far from the walls of the previous scan to prevent interference from the side walls of the previous scan with the probe tip during the subsequent scan. By using a terraced approach, the final mill pocket could be controlled better.

It was also found that the diamond tip would dull during the milling process. The tip sharpness was monitored periodically. A duller tip required a greater deflection of the cantilever to exert a sufficient pressure by the tip on the substrate material in order to cut the substrate, as is consistent with the yield strength or plastic deformation state of the material. The tip is changed when the tip is no longer able to image the surface with enough resolution to accurately determine position of the milling box.

Spring constants between about 49 N/m and 2000 N/m were tested. Hardnesses of material used in semiconductor fabrication vary, which requires using different pressure on the probe tip. For example, using a thick cantilever that is 0.00079″ thick with a spring constant of about 700 N/m, silicon carbide is removed at a rate of 0.1 nm per pass for 250 nm deflection; silicon oxide provides 0.2 nm removal per pass for 150 nm deflection; tungsten provides 0.6 nm per pass with 100 nm deflection; copper and low-k dielectric provide 4.7 nm per pass with 50 nm deflection

The preferred diamond tip end-radius has an end-radius is 10 nm, although the radius will increase over time as the tip wears.

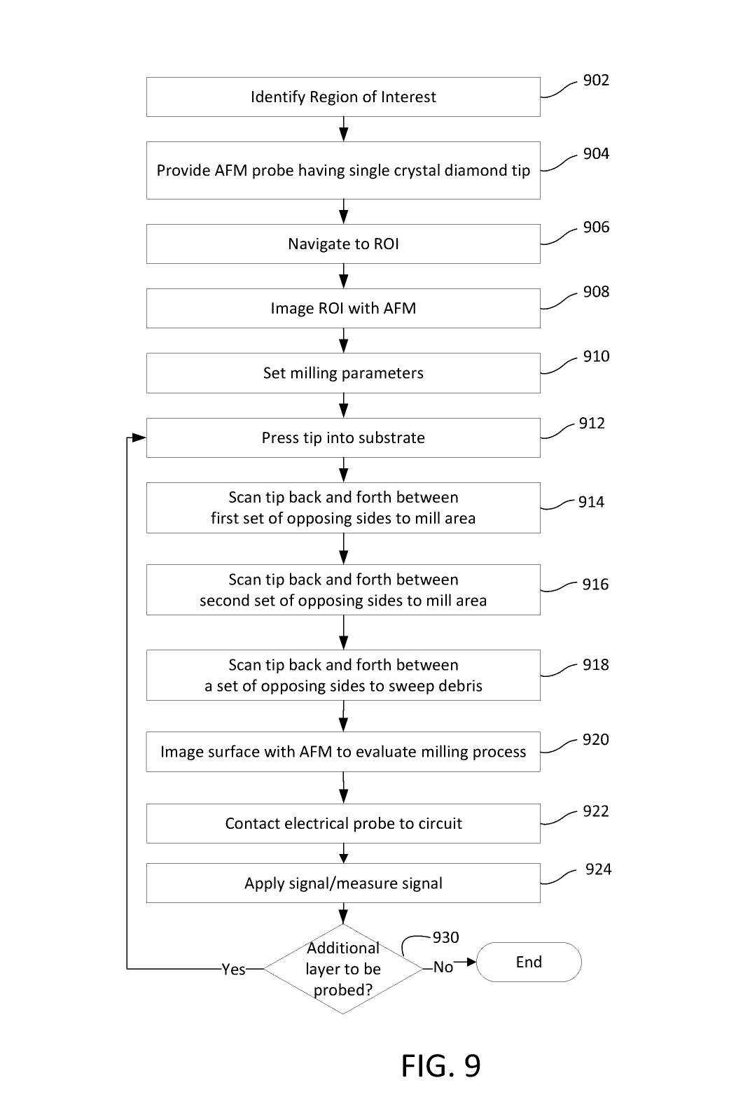

FIG. 9 is a flow chart showing steps for delayering an integrated circuit for electrical probing. The process of delayering and probing typically begins by identifying a region of interest (ROI) through variable means, such as CAD, Optical Microscope Review, SEM/FIB review, or AFM imaging as shown in step 902. In step 904, a scanning probe microscope having a single crystal, facetted diamond tip is provided. In step 906, the probe is navigated to the ROI. In step 908, the ROI is re-imaged with the diamond tip to confirm location. Next, in step 910 parameters for milling are set according to the initial image from the diamond tip and the desired milling pocket dimensions.

In step 912, the diamond probe tip is pressed into the circuit. As described above, the pressure is determined by the cantilever deflection and is chosen based on the hardness of the substrate, the tip diameter, the desired removal rate and the desired smoothness of the finished surface. For each different material type between low-k dielectric, Silicon Oxide, Nitride, Tungsten, Copper, and others, a different pressure is preferred to actually begin cutting the material, and a skilled person can readily determine the required pressure.

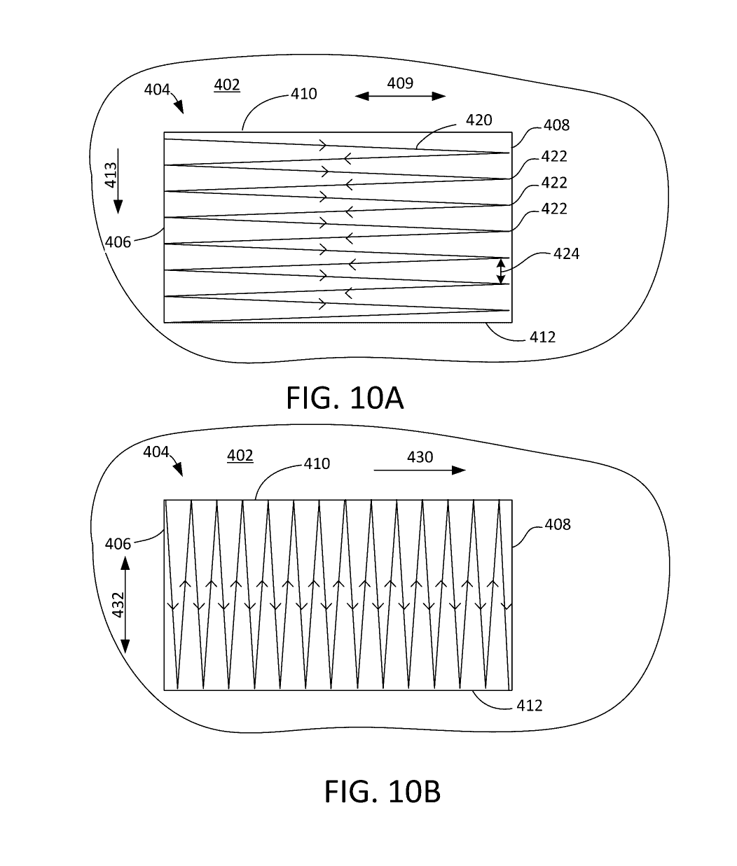

FIGS. 10 and 10B show a part of semiconductor circuit 402 contains an area 404 to be delayered and probed. The area 404 is defined by a first set of opposing sides 406 and 408 and a second set of opposing sides 410 and 412.

In step 914, the probe tip scanned back and forth between from side 406 to side 408 while pressing the probe into the substrate to mill the semiconductor circuit to mill the area 404. During milling, the probe is set to maintain a constant Z-height relative to the sample surface and to move with a constant speed while milling. The probe actuator will vary the pressure of the probe on the circuit to maintain a constant height. The scan path 420 of the probe moves back and forth between sides 406 and 408, in directions 409 while moving more slowly at a constant velocity from side 410 toward side 412 in direction 413. In FIG. 10A direction 409 is referred to as the “fast” axis while direction 413 is referred to as the “slow” axis. This results in a scan path having series of “V”s at the sides 406 and 408. Not that the distance between successive “laps,” that is, portions of the scan without a change in direction, varies at different points of the scan path. Successive laps are closest at the points 422 where the probe changes direction at a side, and the distance 424 between laps is furthest between successive direction changes 422. The angle at points 422 and the distance 424 are determined by the relative speed in directions 409 and direction 413. The relative speeds are chosen depending on the tip diameter to ensure that the laps of the scan path 420 are sufficiently close to produce a suitably smooth surface.

The scan lines are defined by the “scan box” parameters. There can be 10 lines, 70 lines, 100 lines, 250 lines, or 500 lines per scan box (fairly arbitrary but must be an even number). The user can select the number of lines to use. The selected number of scan lines represents a tradeoff between smoothness of cut versus the time it takes to make the cut. Larger number of lines take longer amounts of time to complete. Each line can be considered to be a “lap” of the tip translating forward and backwards in the scan axis. So it takes 10× the time to do a 500 line pass than to do a 50 line pass. If the width of the cut is narrow, a smaller number of lines is necessary since the cut path is dependent eventually on the end-radius of the diamond tip.

The tip velocity is usually fixed (about 25 um/sec) so the number of scan lines linearly increases the duration of the cutting pass. Generally, several milling passes will be necessary to complete the task (from 5× up to 50× or 100× depending on depth).

A common trench could have dimensions of 400 nm in the long axis and 100 nm in the slow axis with a goal of cutting 50 nm deep. In this case, with a 20 nm end-radius diamond tip, the scan lines pitch would be comfortable at 50 and serviceable at 20. It is conceivable that 6 lines would suffice, with 20 nm pitch between each, but in practice more lines is better to the limit that the pitch between passes is much-much smaller than the tip radii (10× or 20× smaller).

While it may be possible to produce a smooth surface by choosing relative velocities to produce sufficiently close laps, this approach can be time consuming. After milling the region 404 as shown in FIG. 10A, the fast and slow axis are switched. In step 916 the tip is scanned repeatedly back and forth between sides 410 and 412, while the probe is moved between side 406 and 408 to mill area 404. In some embodiments, the relative speeds for the probe directions in step 916 are reversed from the relative speeds for the probe in step 914. Alternatively, different speeds could be used in step 916. The goal is to maximize the smoothness of the floor of the delayer area, for the time required to mill.

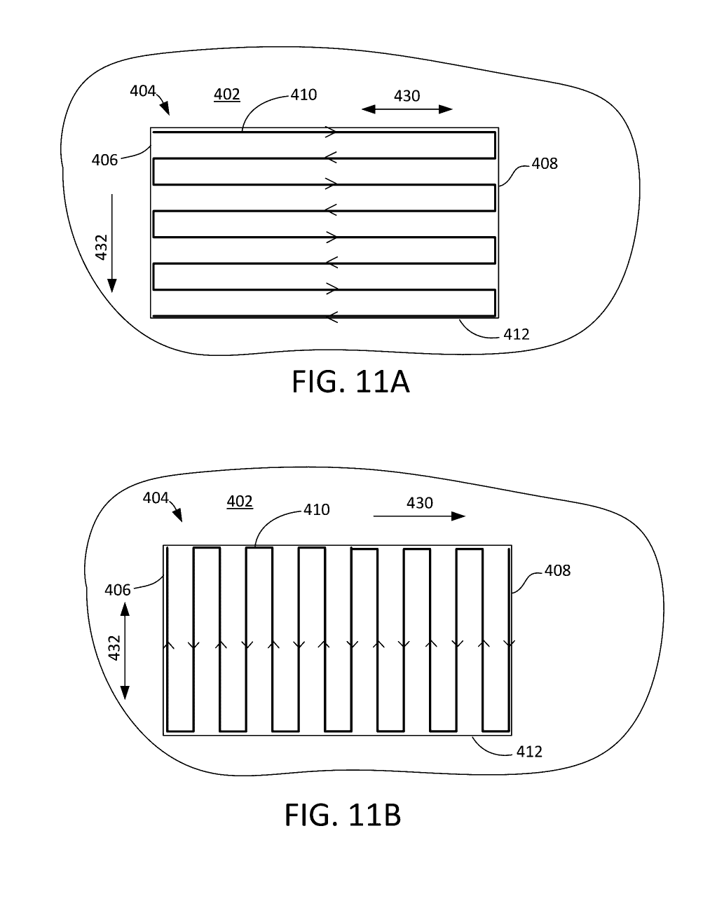

FIGS. 11A and 11B show an alternative scan strategy. Instead of moving at a constant velocity from side 410 to 412 in preforming step 914, the probe is moved parallel to line 430, and then stepped in the direction of 432. The size of the step will vary with the probe diameter. In the embodiment of FIGS. 5A and 5B, each lap of the scan is at a constant distance from the previous lap, which can produce a more even floor. FIG. 11B shows the scan path for step 916 in the alternative embodiment. Because the first scan in step 914 can be different from the second scan in step 916, one could use the scan strategy of FIG. 10A in step 914 and the scan strategy of FIG. 11B in step 916, or any combination of scans.

By performing the milling in two steps in opposite directions, a smoother floor is produced. In step 918, the probe is scanned back and forth to remove debris. In step 920, the milled surface is imaged using the AFM. In step 922, an electrical probe is contacted to the circuit to test its electrical properties. Electrical testing is typically performed using a probe tip that is mounted on adjacent cantilevers on adjacent AFM heads. In step 924, and electrical signal is applied to the sample or to a probe, and a signal corresponding to a property of the circuit is measured.

In decision block 930, it is determined whether an additional layer needs to be tested. If there are no additional layers to be tested, the process is ended. If so, the process is repeated from step 912 to remove the next layer of the semiconductor. After the layer is removed and debris removed in step 912 to 918, the newly exposed layer can be images and electrically tested by contacting an electrical probe in step 922.

Another application is to alter an electrical circuit by cutting a metal line. The application is to first cut an exposed metal line by using a narrow width, long length rectangular milling or scanning pattern. This is to allow the debug of circuits by:

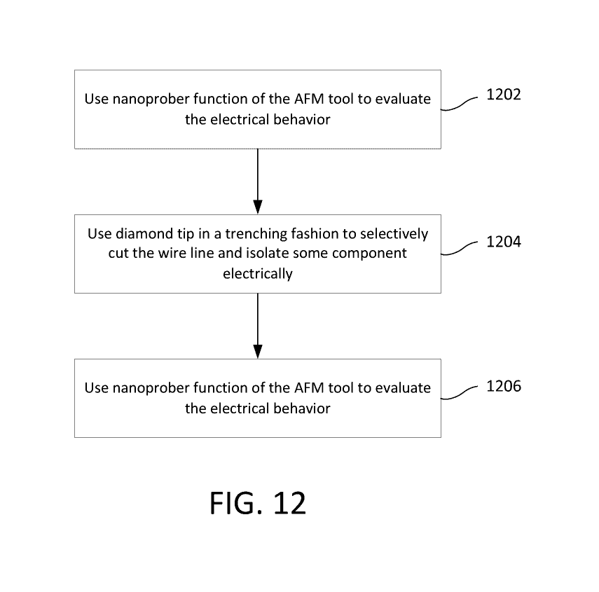

FIG. 12 shows another application in which the AFM is used for circuit evaluation. In step 1202, the nanoprober function of the AFM tool is used to evaluate the electrical behavior of some circuit, for example a short in a circuit that should be open by measuring a first signal. In step 1204, the diamond tip is used in a trenching fashion to selectively cut the wire line and isolate some component electrically by severing an electrical connection on the integrated circuit. In step 1206, the nanoprober function of the AFM is used again to measure a second signal. The difference between the first signal and the second signal allows the user to determine the circuit's electrical behavior to evaluate a characteristic of the integrated circuit. Steps 1202 and 1206 can probe the circuit at the same location, or at different locations. The steps of FIG. 12 can be performed after a conductive layer is exposed by the scanning probe microscope delayering process of FIG. 9.

The technique has been able to sever lines that were at 15 nm pitch and 100's nm pitch. contacting a nanoprobe to a conductor on the integrated circuit to measure a first signal;

Primary variables for milling include the sample material hardness, the diamond tip end-radius (sharpness), force and, more importantly pressure, that is, force/probe contact area. The pressure is generally determined by cantilever deflection. Other variables include the probe translation (scanning) speed, the scan pattern parameters (size, and pitch), and the number of passes.

Some embodiments of the invention provide a method for delayering a region of a semiconductor device on a substrate, the region having at first set of opposing edges and a second set of opposing edges, the method comprising:
repeatedly scanning a single crystal diamond probe tip of a scanning probe microscope back and forth along different paths between a first set of opposing edges while pressing the probe tip into the substrate to mill an area of the semiconductor circuit to remove a layer of material from the region and expose a buried circuit layer;
electrically contacting the exposed circuit layer with an electrical probe; and
measuring a signal from the circuit.

Some embodiments further comprising repeatedly scanning the probe back and forth along different paths between second set of opposing edges while pressing the probe into the substrate to smooth the surface exposed by repeatedly scanning the probe back and forth between first set of opposing edges.

In some embodiments, repeatedly scanning a single crystal diamond probe tip of a scanning probe microscope back and forth to mill an area of the semiconductor circuit mills the area to a first depth and further includes scanning the single crystal diamond probe tip of a scanning probe microscope back and forth to mill a subset of the area to a second depth, to terrace the region.

In some embodiments, the probe tip has a diameter of less than 25 nm.

In some embodiments, repeatedly scanning the probe back and forth between first set of opposing edges and repeatedly scanning the probe back and forth between second set of opposing edges comprises scanning in a constant height mode in which the controller changes the pressure between the probe and the circuit to maintain the probe at a constant height relative to the substrate surface.

Some embodiments further comprise repeatedly scanning the probe back and forth between the first set of opposing edges to remove debris created by repeatedly scanning the probe back and forth between first set of opposing edges while pressing the probe into the substrate to mill the semiconductor circuit.

In some embodiments, repeatedly scanning the probe back and forth between first set of opposing edges includes, before changing the scan direction, stepping the probe in a direction having a component normal to the scan.

In some embodiments, repeatedly scanning the probe back and forth between first set of opposing edges comprises scanning the probe in a serpentine pattern.

In some embodiments, repeatedly scanning the probe back and forth between first set of opposing edges includes superimposing a motion of the probe in direction parallel to one of the two opposing walls while moving the probe back and forth between the opposing walls so that probe moves once between a second set of opposing side while repeatedly scanning the probe back and forth between first set of opposing edges.

In some embodiments, repeatedly scanning the probe back and forth between first set of opposing edges includes scanning the probe back and forth such that the scan pattern forms a series of “V”-shaped paths at the opposing sides.

Some embodiment further comprises forming a scanning probe microscope image of the delayered region.

In some embodiments, the scanning probe microscope comprises an atomic force microscope.

In some embodiments, the scanning probe microscope includes a cantilever to which the tip is attached; and repeatedly scanning the probe back and forth along different paths between a first set of opposing edges comprises scanning the probe back and forth in a direction substantially normal to the cantilever.

In some embodiments, the scanning probe microscope includes a cantilever to which the probe tip is attached such that the tip of the probe extends from beneath the cantilever so that the probe tip can be viewed from above while contacting the surface without the view being blocked by the cantilever.

Some embodiments further comprise observing the probe tip in contact with the work piece.

In some embodiments, the scanning probe microscope includes a cantilever to which the probe tip is attached with a flat facet is facing backwards toward the cantilever.

Some embodiments provide a method analyzing an integrated circuit, comprising:
contacting a nanoprobe to a conductor on the integrated circuit to measure a first signal;
using the probe of a scanning probe microscope, severing an electrical connection on the integrated circuit; and
contacting a nanoprobe to a conductor on the integrated circuit to measure a second signal;
determining from the different between the first signal and the second signal a characteristic of the integrated circuit.

In some embodiments, using the probe of a scanning probe microscope to sever an electrical connection comprises using a faceted diamond probe tip to sever the connection.

In some embodiments, contacting a nanoprobe to a conductor to measure a first signal and contacting a nanoprobe to a conductor to measure a second signal comprise contacting the nanoprobe to the same conductor.

Some embodiments further comprise using the probe of a scanning probe microscope to delayer a portion of the integrated circuit prior to measuring the first signal.

Some embodiments provide a scanning probe microscope, comprising:
an actuator;
a cantilever attached to the actuator;
a faceted diamond probe tip attached to the cantilever;
a controller for controlling the scanning probe microscope; and
a computer memory storing computer instructions for performing the method of any of the above claims.

Some embodiments further comprise a microscope for observing the work piece from above and in which the faceted diamond probe is attached to the cantilever such that the diamond probe extends from underneath the probe tip so that it can be viewed from above by the microscope.

In some embodiments, the facetted diamond probe is oriented on the cantilever such that a flat side of the diamond faces along the cantilever towards the actuator.

A preferred method or apparatus of the present invention has many novel aspects, and because the invention can be embodied in different methods or apparatuses for different purposes, not every aspect need be present in every embodiment. Moreover, many of the aspects of the described embodiments may be separately patentable. The invention has broad applicability and can provide many benefits as described and shown in the examples above. The embodiments will vary greatly depending upon the specific application, and not every embodiment will provide all of the benefits and meet all of the objectives that are achievable by the invention.

It should be recognized that embodiments of the present invention can be implemented via computer hardware, a combination of both hardware and software, or by computer instructions stored in a non-transitory computer-readable memory. The methods can be implemented in computer programs using standard programming techniques—including a non-transitory computer-readable storage medium configured with a computer program, where the storage medium so configured causes a computer to operate in a specific and predefined manner—according to the methods and figures described in this Specification. Each program may be implemented in a high level procedural or object oriented programming language to communicate with a computer system. However, the programs can be implemented in assembly or machine language, if desired. In any case, the language can be a compiled or interpreted language. Moreover, the program can run on dedicated integrated circuits programmed for that purpose.

Further, methodologies may be implemented in any type of computing platform, including but not limited to, personal computers, mini-computers, main-frames, workstations, networked or distributed computing environments, computer platforms separate, integral to, or in communication with charged particle tools or other imaging devices, and the like. Aspects of the present invention may be implemented in machine readable code stored on a non-transitory storage medium or device, whether removable or integral to the computing platform, such as a hard disc, optical read and/or write storage mediums, RAM, ROM, and the like, so that it is readable by a programmable computer, for configuring and operating the computer when the storage media or device is read by the computer to perform the procedures described herein. Moreover, machine-readable code, or portions thereof, may be transmitted over a wired or wireless network. The invention described herein includes these and other various types of non-transitory computer-readable storage media when such media contain instructions or programs for implementing the steps described above in conjunction with a microprocessor or other data processor. The invention also includes the computer itself when programmed according to the methods and techniques described herein.

Computer programs can be applied to input data to perform the functions described herein and thereby transform the input data to generate output data. The output information is applied to one or more output devices such as a display monitor. In preferred embodiments of the present invention, the transformed data represents physical and tangible objects, including producing a particular visual depiction of the physical and tangible objects on a display.

Although much of the previous description is directed at mineral samples from drill cuttings, the invention could be used to prepare samples of any suitable material. The terms “work piece,” “sample,” “substrate,” and “specimen” are used interchangeably in this application unless otherwise indicated. Further, whenever the terms “automatic,” “automated,” or similar terms are used herein, those terms will be understood to include manual initiation of the automatic or automated process or step.

In the following discussion and in the claims, the terms “including” and “comprising” are used in an open-ended fashion, and thus should be interpreted to mean “including, but not limited to . . . .” To the extent that any term is not specially defined in this specification, the intent is that the term is to be given its plain and ordinary meaning. The accompanying drawings are intended to aid in understanding the present invention and, unless otherwise indicated, are not drawn to scale.

The various features described herein may be used in any functional combination or sub-combination, and not merely those combinations described in the embodiments herein. As such, this disclosure should be interpreted as providing written description of any such combination or sub-combination.

Although the present invention and its advantages have been described in detail, it should be understood that various changes, substitutions and alterations can be made to the embodiments described herein without departing from the scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

We claim as follows:

1. A method for delayering a region of a semiconductor device on a substrate, the region having at first set of opposing edges and a second set of opposing edges, the method comprising:
repeatedly scanning a single crystal diamond probe tip of a scanning probe microscope back and forth along different paths between a first set of opposing edges while pressing the probe tip into the substrate to mill an area of the semiconductor circuit to remove a layer of material from the region and expose a buried circuit layer;
electrically contacting the exposed circuit layer with an electrical probe; and
measuring a signal from the circuit.

2. The method of claim 1, further comprising repeatedly scanning the probe back and forth along different paths between second set of opposing edges while pressing the probe into the substrate to smooth the surface exposed by repeatedly scanning the probe back and forth between first set of opposing edges.

3. The method of claim 1, in which repeatedly scanning a single crystal diamond probe tip of a scanning probe microscope back and forth to mill an area of the semiconductor circuit mills the area to a first depth and further includes scanning the single crystal diamond probe tip of a scanning probe microscope back and forth to mill a subset of the area to a second depth, to terrace the region.

4. The method of claim 1, in which the probe tip has a diameter of less than 25 nm

5. The method of claim 1, in which repeatedly scanning the probe back and forth between first set of opposing edges and repeatedly scanning the probe back and forth between second set of opposing edges comprises scanning in a constant height mode in which the controller changes the pressure between the probe and the circuit to maintain the probe at a constant height relative to the substrate surface.

6. The method of claim 1, further comprising repeatedly scanning the probe back and forth between the first set of opposing edges to remove debris created by repeatedly scanning the probe back and forth between first set of opposing edges while pressing the probe into the substrate to mill the semiconductor circuit.

7. The method of claim 1, in which repeatedly scanning the probe back and forth between first set of opposing edges includes, before changing the scan direction, stepping the probe in a direction having a component normal to the scan.

8. The method of claim 1, in which repeatedly scanning the probe back and forth between first set of opposing edges comprises scanning the probe in a serpentine pattern.

9. The method of claim 1, in which repeatedly scanning the probe back and forth between first set of opposing edges includes superimposing a motion of the probe in direction parallel to one of the two opposing walls while moving the probe back and forth between the opposing walls so that probe moves once between a second set of opposing side while repeatedly scanning the probe back and forth between first set of opposing edges.

10. The method of claim 1, in which repeatedly scanning the probe back and forth between first set of opposing edges includes scanning the probe back and forth such that the scan pattern forms a series of “V”-shaped paths at the opposing sides.

11. The method of claim 1, further comprising forming a scanning probe microscope image of the delayered region.

12. The method of claim 1, in which the scanning probe microscope comprises an atomic force microscope.

13. The method of claim 1, in which:
the scanning probe microscope includes a cantilever to which the tip is attached; and
repeatedly scanning the probe back and forth along different paths between a first set of opposing edges comprises scanning the probe back and forth in a direction substantially normal to the cantilever.

14. The method of claim 1, in which the scanning probe microscope includes a cantilever to which the probe tip is attached such that the tip of the probe extends from beneath the cantilever so that the probe tip can be viewed from above while contacting the surface without the view being blocked by the cantilever.

15. The method of claim 1, further comprising observing the probe tip in contact with the work piece.

16. The method of claim 1, in which the scanning probe microscope includes a cantilever to which the probe tip is attached with a flat facet is facing backwards toward the cantilever.

17. A method analyzing an integrated circuit, comprising:
contacting a nanoprobe to a conductor on the integrated circuit to measure a first signal;
using the probe of a scanning probe microscope, severing an electrical connection on the integrated circuit; and
contacting a nanoprobe to a conductor on the integrated circuit to measure a second signal;
determining from the different between the first signal and the second signal a characteristic of the integrated circuit.

18. The method of claim 17 in which using the probe of a scanning probe microscope to sever an electrical connection comprises using a faceted diamond probe tip to sever the connection.

19. The method of claim 17 in which contacting a nanoprobe to a conductor to measure a first signal and contacting a nanoprobe to a conductor to measure a second signal comprise contacting the nanoprobe to the same conductor.

20. The method of claim 17 further comprising using the probe of a scanning probe microscope to delayer a portion of the integrated circuit prior to measuring the first signal.

21. A scanning probe microscope, comprising:
an actuator;
a cantilever attached to the actuator;
a faceted diamond probe tip attached to the cantilever;
a controller for controlling the scanning probe microscope; and
a computer memory storing computer instructions for performing the method of claim 1.

22. The scanning probe microscope of claim 21 further comprising a microscope for observing the work piece from above and in which the faceted diamond probe is attached to the cantilever such that the diamond probe extends from underneath the probe tip so that it can be viewed from above by the microscope.

23. The scanning probe microscope of claim 21 in which the facetted diamond probe is oriented on the cantilever such that a flat side of the diamond faces along the cantilever towards the actuator.
